(19) United States
(12) Patent Application Publication
(10) Pub. No.: US 2025/0233029 A1
(43) Pub. Date: Jul. 17, 2025

(54) SEMICONDUCTOR DEVICE AND TEST METHOD OF THE SAME

(71) Applicant: Samsung Electronics Co., Ltd., Suwon-si (KR)

(72) Inventors: Jungwoo JANG, Suwon-si (KR); Mincheol KWAK, Suwon-si (KR); Woohyun SON, Suwon-si (KR); Taehong JANG, Suwon-si (KR)

(73) Assignee: Samsung Electronics Co., Ltd., Suwon-si (KR)

(21) Appl. No.: 18/971,344

(22) Filed: Dec. 6, 2024

(30) Foreign Application Priority Data
Jan. 12, 2024 (KR) 10-2024-0005444

(51) Int. Cl. H01L 21/66; H01L 23/00; H01L 23/498; H01L 25/065

(52) U.S. Cl. CPC H01L 22/34; H01L 23/49827; H01L 25/0657; H01L 24/05; H01L 24/08; H01L 24/13; H01L 24/16; H01L 2224/05568; H01L 2224/08146; H01L 2224/08148; H01L 2224/13023; H01L 2224/16148; H01L 2225/06513; H01L 2225/06517; H01L 2225/06541; H01L 2924/14335

(57) ABSTRACT

A semiconductor device according to some example embodiments comprises: a reference die configured to generate a test signal based on a first seed and transmit both an output clock signal and the test signal, and a target die configured to receive the output clock signal as an input clock signal though at least one through-silicon via TSV, capture the test signal as captured data based on the input clock signal, and compare a comparison pattern generated based on the first seed and the captured data.

### CROSS-REFERENCE TO RELATED APPLICATION

This application claims priority to and the benefit of Korean Patent Application No. 10-2024-0005444 filed at the Korean Intellectual Property Office on Jan. 12, 2024, the entire contents of which are incorporated herein by reference.

### BACKGROUND

### (a) Field

The present inventive concepts relate to semiconductor devices and methods for testing semiconductor devices.

### (b) Description of the Related Art

As the size of electronic portable devices is being reduced, the semiconductor devices installed inside these portable electronic devices are also gradually becoming smaller. In order to integrate more circuits in a limited space, multi-chip package memory, in which a plurality of memory chips that perform two or more different functions are stacked, has been recently manufactured.

Meanwhile, stacking a large number of semiconductor dies can increase the load on the signal path. Increased load on the signal path can limit the speed of signal transmission between semiconductor dies and between a semiconductor die and an external device.

### SUMMARY

Some example embodiments of the present inventive concepts provide a semiconductor device that is configured to transmit data and/or a test method for the semiconductor device based on considering the delay time of through-silicon via TSV electrodes.

A semiconductor device according to some example embodiments may include a reference die configured to generate a test signal based on a first seed and transmit an output clock signal and the test signal, and a target die configured to receive the output clock signal as an input clock signal through at least one through-silicon via TSV, capture the test signal as captured data based on the input clock signal, and compare a comparison pattern generated based on the first seed and the captured data.

A memory die according to some example embodiments may include a transmitter configured to generate a first test signal based on a first seed and transmit both an output clock signal and a first test signal, and a receiver configured to receive a second test signal generated based on a second seed and an input clock signal through at least one through-silicon via TSV, and capture the second test signal as captured data based on the input clock signal.

A testing method for a semiconductor device according to some example embodiments may include generating a first test pattern based on a first seed, storing the first test pattern in a first-in first-out FIFO circuit based on a reference clock signal, generating an output clock signal based on modulating the reference clock signal, receiving a ready signal indicating whether a target die is ready to receive a first test signal, and in response to a determination that the ready signal is at an enable level, transmitting a VALID signal to control an operation of the target die to the target die, and transmitting the first test signal based on the output clock signal.

### BRIEF DESCRIPTION OF THE DRAWINGS

FIG. 1 is a diagram illustrating a semiconductor device according to some example embodiments.

FIG. 2 is a diagram illustrating a configuration of a semiconductor device according to some example embodiments.

FIG. 3 is a diagram illustrating a reference die according to some example embodiments.

FIG. 4 is a diagram specifically illustrating a configuration of the reference die according to FIG. 3 according to some example embodiments.

FIG. 5 is a timing diagram illustrating the operation timing of the reference die according to FIG. 3 according to some example embodiments.

FIG. 6 is a diagram illustrating a target die according to some example embodiments.

FIG. 7 is a diagram illustrating in detail a configuration of a target die according to FIG. 6 according to some example embodiments.

FIG. 8 is a timing diagram illustrating the operation timing of a target die according to some example embodiments.

FIG. 9 is a graph illustrating the change in error rate according to some example embodiments.

FIG. 10 is a timing diagram illustrating the operation timing of a target die according to some example embodiments.

FIG. 11 is a diagram illustrating a method of operating a semiconductor device according to some example embodiments.

FIG. 12 is a diagram illustrating a configuration of a semiconductor device according to some example embodiments.

FIG. 13 is a plan view illustrating the inside of a memory chip according to some example embodiments.

FIG. 14 is a diagram illustrating a semiconductor device according to some example embodiments.

FIG. 15 is a block diagram illustrating a data center according to some example embodiments.

### DETAILED DESCRIPTION

Below, with reference to the attached drawings, some example embodiments of the present inventive concepts will be described in detail so that those skilled in the art can easily implement the present inventive concepts. However, the present inventive concepts may be implemented in many different forms and are not limited to the example embodiments described herein.

In order to clearly explain the present inventive concepts in the drawings, parts that are not related to the description are omitted, and similar parts are given similar reference numerals throughout the specification. In the flowchart described with reference to the drawings, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

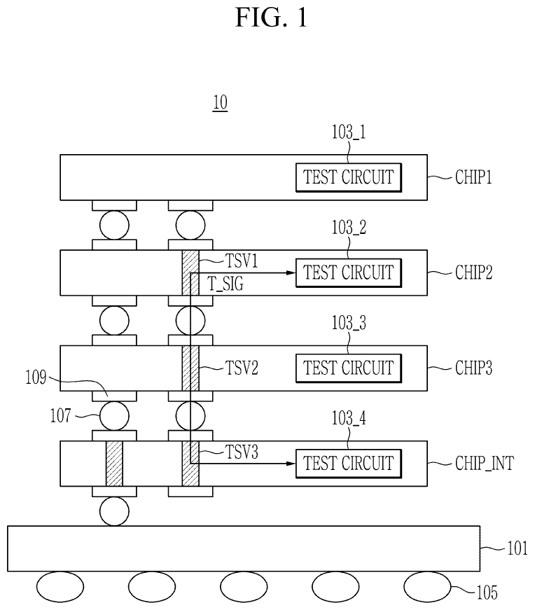

FIG. 1 is a diagram illustrating a semiconductor device according to some example embodiments.

As shown in FIG. 1, the semiconductor device 10 includes a substrate 101, a transfer memory chip CHIP_INT sequentially stacked on the substrate 101, and a plurality of memory chips (CHIP1, CHIP2, CHIP3) sequentially stacked on the substrate 101.

The semiconductor device 10 can be implemented as package on package (POP), ball grid arrays (BGA), chip scale packages (CSP), plastic leaded chip carrier PLCC), plastic dual in-line package (PDIP), chip on board (COB), ceramic dual in-line package (CERDIP), plastic metric quad flat pack (MQFP), thin quad flat pack (TQFP), small-outline integrated circuit (SOIC), shrink small outline package (SSPO), thin small outline package (TSOP), system in package multi-chip package (MCP), wafer-level package (WLP), or wafer-level processed stack package (WSP).

The semiconductor device 10 may include a plurality of balls 105 that can exchange signals with the outside of the semiconductor device 10.

The transmission memory chip CHIP_INT may transmit signals (e.g., commands) received from the outside (e.g., from an exterior of the transmission memory chip CHIP_INT to a plurality of memory chips (CHIP1, CHIP2, CHIP3) or transmit data of the memory chips (CHIP1, CHIP2, CHIP3) to the outside.

A plurality of memory chips (CHIP1, CHIP2, CHIP3) may be stacked vertically (e.g., in a direction perpendicular to an in-plane direction of the substrate 101) on the transfer memory chip CHIP_INT. A plurality of memory chips (CHIP1, CHIP2, CHIP3) and a transfer memory chip CHIP_INT may be connected by means of an electrical connection. For example, a plurality of memory chips (CHIP1, CHIP2, CHIP3) and a transfer memory chip CHIP_INT can be interconnected by means of through-silicon vias (TSV) (TSV1, TSV2, TSV3) and a plurality of balls 107 and pads 109. The plurality of memory chips (CHIP1, CHIP2, CHIP3) and the transmission memory chip CHIP_INT can transmit and receive data, signals, etc. by means of through electrodes, which may be defined by one or more through-silicon vias (TSV1, TSV2, TSV3). The positions of the plurality of balls 107 and the through electrodes TSV1, TSV2, and TSV3 are not limited to those shown in FIG. 1. It will be understood that balls 107 and 105 and pads 109 may each independently comprise any conductive material, for example copper.

As the number (quantity) of stacked memory chips sharing a signal path using a through electrode increases, the load on the signal path may increase. As the load on the signal path increases, the rising time and falling time of the transmitted signal increase, which may prevent the signal from being transmitted normally. Additionally, when transmitting signals such as commands or data between a plurality of adjacent memory chips (CHIP1, CHIP2, CHIP3), TSV delay time may be required to pass through the through electrodes (TSV1, TSV2, TSV3). TSV delay time can vary depending on various factors. For example, TSV delay time may vary due to factors that are difficult to predict, such as parasitic parameters or process differences. That is, the time taken to transmit data between the transfer memory chip CHIP_INT and the plurality of memory chips (CHIP1, CHIP2, CHIP3) may be uncertain. Therefore, performance may deteriorate when transmitting data within a semiconductor device (e.g., between a different memory chips of a plurality of memory chips).

Meanwhile, the semiconductor device 10 may include a plurality of test circuits 103_1, 103_2, 103_3, and 103_4. Each of the plurality of test circuits 103_1, 103_2, 103_3, and 103_4 can detect optimal conditions for transferring data between the plurality of memory chips (CHIP1, CHIP2, CHIP3) and the transfer memory chip CHIP_INT. Specifically, the first memory chip CHIP1 may include a first test circuit 103_1. The second memory chip CHIP2 may include a second test circuit 103_2. The third memory chip CHIP3 may include a third test circuit 103_3. The transfer memory chip CHIP_INT may include a fourth test circuit 103_4.

In some example embodiments, the fourth test circuit 103_4 selects one option from a plurality of particular (or, alternatively, predetermined) options and transmits a test signal T_SIG to at least the second test circuit 103_2 using the selected option. The second test circuit 103_2 may generate a comparison result by comparing the test signal T_SIG and the test pattern generated by the second test circuit 103_2 itself. A comparison of signals and patterns as described herein may include determining a difference between (e.g., a subtraction of) the compared signals and/or patterns. For example, a comparison result of comparing the test signal T_SIG and the test pattern generated by the second test circuit 103_2 itself may include information indicating a difference between (e.g., a subtraction of) the test signal T_SIG and the test pattern. The fourth test circuit 103_4 may transmit a test signal T_SIG to the second test circuit 103_2 while changing options so that the second test circuit 103_2 generates comparison results for each of a plurality of options.

In FIG. 1, the fourth test circuit 103_4 is shown as transmitting the test signal T_SIG to the second test circuit 103_2, but the present inventive concepts are not limited thereto and the second test circuit 103_2 transmits the test signal T_SIG to the second test circuit 103_2. A test signal T_SIG may be transmitted to the fourth test circuit 103_4, or any test circuit may transmit a test signal to another test circuit.

In FIG. 1, it is shown that three memory chips (CHIP1, CHIP2, CHIP3) are stacked vertically on the transfer memory chip CHIP_INT, but the present inventive concepts are not limited to this, and any number of memory chips can also be stacked on the transfer memory chip CHIP_INT.

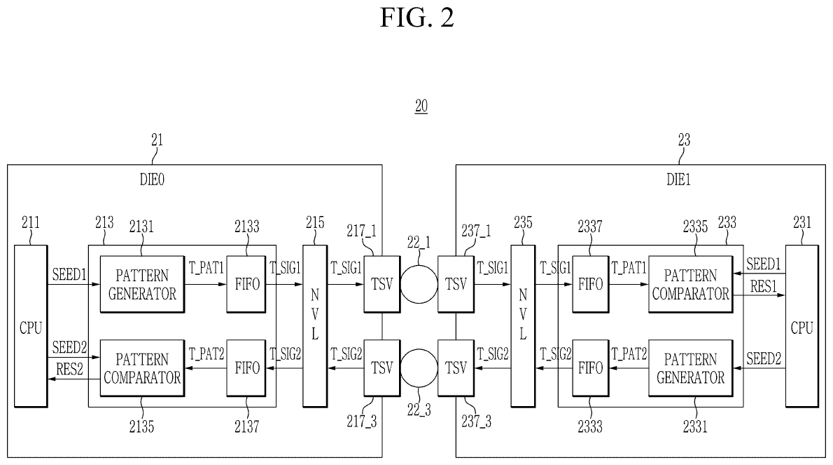

FIG. 2 is a diagram illustrating a configuration of a semiconductor device according to some example embodiments.

Specifically, the semiconductor device 20 includes a first die 21 and a second die 23.

The first die 21 and the second die 23 may be connected through a plurality of TSVs 217_1, 217_3, 237_1, 237_3 and balls 22_1 and 22_3.

The first die 21 may include a CPU 211, a test circuit 213, a near via logic NVL 215, and a plurality of TSVs 217_1 and 217_3.

The CPU 211 can control the configuration within the test circuit 213. In some example embodiments, the CPU 211 may generate a first seed SEED1 for generating the test signal T_SIG1. The CPU 211 may generate a second seed SEED2 to generate a comparison result. The CPU 211 may transmit the generated first seed SEED1 and second seed SEED2 to the test circuit 213. The CPU 211 can select optimal conditions based on the comparison result RES2 received from the test circuit 213.

The test circuit 213 may generate a test signal T_SIG1 based on the first seed SEED1 received from the CPU 211. The test circuit 213 may generate a comparison result RES2 based on the second seed SEED2 received from the CPU 211.

The test circuit 213 may include a pattern generator 2131, a first FIFO (First-In First-Out) circuit 2133 connected to the pattern generator 2131, a pattern comparator 2135, and a second FIFO circuit 2137 connected to the pattern comparator 2135.

The pattern generator 2131 and the first FIFO circuit 2133 may generate a test signal T_SIG1.

Specifically, the pattern generator 2131 may generate a test pattern T_PAT1 based on the first seed SEED1 received from the CPU 211. In some example embodiments, the pattern generator 2131 may generate the test pattern T_PAT1 based on a linear feedback shift register LFSR algorithm performed on a bit-by-bit basis. In some example embodiments, the pattern generator 2131 is a type of counter and can generate a unidirectional pseudorandom pattern. In some example embodiments, the pattern generator 2131 may generate a toggle pattern according to the operating conditions of the first die 21. The pattern generator 2131 may generate the test pattern T_PAT1 with a particular (or, alternatively, predetermined) number of bits. In the case of the pattern generator 2131 that generates the test pattern T_PAT1 based on the LFSR algorithm, if the same seed value is input to the pattern generator 2131, the same test pattern T_PAT1 can be generated regardless of the number (quantity) of trials.

The first FIFO (First-In First-Out) circuit 2133 may store the test pattern T_PAT1 generated by the pattern generator 2131. The first FIFO circuit 2133 may output (transmit) the stored test pattern T_PAT1 to an NVL 215 as the test signal T_SIG1 based on the internal clock, which may be a clock implemented by at least a portion of the first die 21, including for example the CPU 211, the test circuit 213, the first FIFO circuit 2133, or the like.

A second FIFO circuit 2137 can receive a test signal T_SIG2 received from the outside through the NVL 215. The second FIFO circuit 2137 may store the received test signal T_SIG2. The second FIFO circuit 2137 may output the stored test signal T_SIG2 as the test pattern T_PAT2 to a pattern comparator 2135 based on the internal clock, which may be a clock implemented by at least a portion of the first die 21, including for example the CPU 211, the test circuit 213, the second FIFO circuit 2137, or the like.

A test circuit 213 is described as including a first FIFO circuit 2133 and the second FIFO circuit 2137, but a single FIFO circuit can perform the operations of both the first FIFO circuit 2133 and the second FIFO circuit 2137.

The pattern comparator 2135 may generate a comparison pattern based on the second seed SEED2 received from the CPU 211. The pattern comparator 2135 may compare the comparison pattern with the test pattern T_PAT2 received from the second FIFO circuit 2137 and generate the comparison result RES2. The comparison may include determining a difference (e.g., subtraction) between the test pattern T_PAT2 and the comparison pattern, and the comparison result RES2 may indicate the difference (e.g., as a subtraction result).

A second die 23 may include a CPU 231, a test circuit 233, an NVL 235, and a plurality of TSVs 237_1 and 237_3. The test circuit 233 includes a pattern generator 2331, a first FIFO circuit 2333 connected to the pattern generator 2331, a pattern comparator 2335, and a second FIFO circuit 2337 connected to the pattern comparator 2335.

Near via logic NVL (215, 235) may be logic located around the TSVs (217_1, 217_3, 237_1, 237_3). Signals generated by each die can be transmitted to other dies through NVLs (215, 235) and TSVs (217_1, 217_3, 237_1, 237_3). In some example embodiments, NVLs 215 and 235 may be a type of register.

A reference die may be a die that includes a test circuit that generates test signals. A target die may be a die that includes a test circuit that receives a test signal from a reference die and generates a comparison result based on the received test signal. Specifically, the target die may detect optimal conditions for the reference die to transmit a test signal based on the comparison result. In some example embodiments, the reference die may transmit a test signal while (e.g., concurrently with) modulating options such as peak-to-noise ratio PnR, clock frequency, and/or delay. The target die can determine optimal data transmission conditions for transmitting a signal that passes through a plurality of TSVs based on the comparison result.

Hereinafter, a description will be made assuming that a first die 21 is a reference die and a second die 23 is a target die. That is, the test circuit 213 of the first die 21 may generate the test signal T_SIG1, and the test circuit 233 of the second die 23 may generate the comparison result RES1.

The CPU 211 may generate a first seed SEED1 for generating the test signal T_SIG1. The CPU 211 may transmit the generated first seed SEED1 to the test circuit 213. A pattern generator 2131 and the first FIFO circuit 2133 may generate the test signal T_SIG1 based on the first seed SEED1. The test signal T_SIG1 may be transmitted to the second die 23 through the NVL 215, a ball 22_1, and a plurality of TSVs 217_1 and 237_1. The test signal T_SIG1 may pass through a plurality of TSVs (217_1, 237_1) and the ball 22_1, and may be transmitted to the test circuit 233 while being subject to various unpredictable influences.

Meanwhile, the CPU 231 may generate a first seed SEED1 corresponding to the test signal T_SIG1 to generate the comparison result RES1. In some example embodiments, the first seed SEED1 generated by the CPU 231 may be identical to the first seed SEED1 generated by the CPU 211, although example embodiments are not limited thereto. The CPU 231 may transmit the first seed SEED1 to the test circuit 233. The test circuit 233 may generate a comparison pattern based on the first seed SEED1 received from the CPU 231, and generate a comparison result RES1 by comparing (e.g., determining a difference between) the test signal T_SIG1 and the comparison pattern, where the comparison result RES1 may indicate a difference between the test signal T_SIG1 as received by the test circuit 233 and the comparison pattern that is generated at the test circuit 233. In some example embodiments, the comparison pattern is generated by the test circuit 233 via an identical algorithm or process that is used by the test circuit 213 to generate the test signal T_SIG1, for example such that the comparison pattern generated by the test circuit 233 may be identical to the test signal T_SIG1 that is initially transmitted from the test circuit 213 (e.g., prior to transmission of the test signal T_SIG1 from the NVL 215). The CPU 231 can receive comparison results from a pattern comparator 2335 and the second FIFO circuit 2337, and based on the comparison results, the CPU 231 can determine the optimal option for the first die 21 to transmit data to the second die 23.

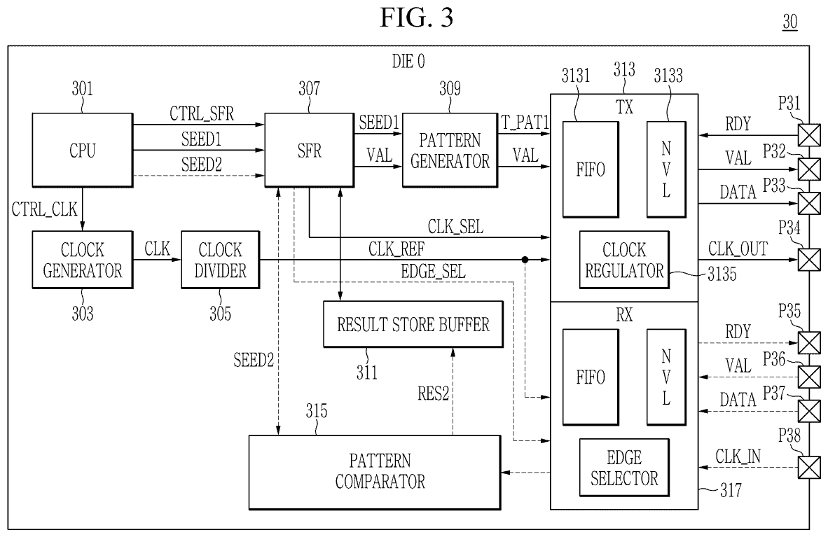

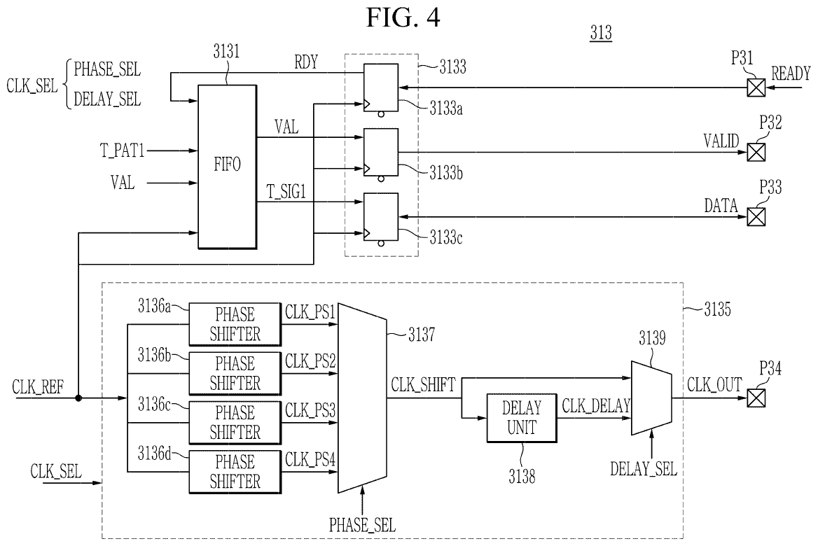

FIG. 3 is a diagram illustrating a reference die according to some example embodiments. FIG. 4 is a diagram specifically illustrating a configuration of the reference die according to FIG. 3 according to some example embodiments. In some example embodiments, the reference die 30 may include or may be included in the first die 21 and/or the second die 23 shown in FIG. 2.

The reference die 30 includes a CPU 301, a clock generator 303, a special function register SFR 307, a pattern generator 309, a result storage buffer 311, a pattern comparator 315, a transmitter 313, a receiver 317, and a plurality of pads (P31, P32, P33, P34, P35, P36, P37, and P38).

The CPU 301 may determine (e.g., generate, select, etc.) a seed for generating the test pattern T_PAT1.

The CPU 301 may generate a clock control signal CTRL_CLK to control the clock generator 303. The clock control signal CTRL_CLK may be a signal that controls the clock generator 303 to generate the clock signal CLK. The CPU 301 may transmit the clock control signal CTRL_CLK to the clock generator 303.

The CPU 301 may generate an SFR control signal CTRL_SFR to control the SFR 307. The SFR control signal CTRL_SFR may be a signal for selecting one of a plurality of options stored in the SFR 307. The CPU 301 may transmit the SFR control signal CTRL_SFR and the first seed SEED1 to the SFR 307.

The clock generator 303 may generate a clock signal CLK. Components within the reference die 30 may operate based on the clock signal CLK (also referred to herein as an internal clock). In some example embodiments, the clock generator 303 may generate the clock signal CLK based on the clock control signal CTRL_CLK. The clock generator 303 may transmit a clock signal CLK to a clock divider 305.

The clock divider 305 may receive the clock signal CLK from the clock generator 303 and divide the clock signal CLK to generate a reference clock signal CLK_REF. In some example embodiments, the clock divider 305 may divide the clock signal CLK by a constant phase difference to generate the reference clock signal CLK_REF. For example, the clock divider 305 may divide the clock signal CLK by two to generate the reference clock signal CLK_REF. The clock divider 305 may transmit a reference clock signal CLK_REF to a transmitter 313.

A special function register SFR 307 can store a plurality of particular (or, alternatively, predetermined) options. In some example embodiments, the special function register SFR 307 may be a register that stores a plurality of options that may determine the data transmission characteristics of the transmitter 313. For example, SFR 307 may store multiple clock options. A plurality of clock options may include a first clock with a first phase and a first delay, a second clock with a first phase and a second delay, a third clock with a second phase and a first delay, a fourth clock with a second phase and a second delay, etc.

The SFR 307 may generate a clock selection signal CLK_SEL based on the SFR control signal CTRL_SFR. The clock selection signal CLK_SEL may be a signal for determining the phase and delay that the clock regulator 3135 applies to the reference clock signal CLK_REF. For example, the SFR control signal CTRL_SFR may be a signal indicating one of a plurality of clock options stored in the SFR 307. The SFR 307 may transmit a clock selection signal CLK_SEL to the transmitter 313. That is, the SFR 307 may transmit to the transmitter 313 the clock selection signal CLK_SEL generated based on a clock option selected based on the SFR control signal CTRL_SFR among a plurality of particular (or, alternatively, predetermined) clock options.

The SFR 307 may generate a VALID signal VAL based on the SFR control signal CTRL_SFR.

The VALID signal VAL may be a signal for controlling the operation of the target die. When the target die receives a VALID signal VAL at an enable level (e.g., a signal magnitude corresponding to an “enable state”) from the reference die 30, the target die may store the data signal DATA received from the reference die 30. When the target die receives a VALID signal VAL at a disable level (e.g., a signal magnitude corresponding to a “disable state”) from the reference die 30, the target die may not store the data signal DATA received from the reference die 30.

The SFR 307 may transmit a VALID signal VAL and a first seed SEED1 to the pattern generator 309.

The pattern generator 309 may generate a test pattern based on the first seed SEED1 received from the SFR 307. In some example embodiments, the pattern generator 309 may generate test pattern T_PAT1 based on the LFSR algorithm. In some example embodiments, the pattern generator 309 may generate the same test pattern T_PAT1 when receiving the same seed value. The pattern generator 309 may generate a test pattern with a particular (or, alternatively, predetermined) number of bits.

The pattern generator 309 may deliver a test pattern T_PAT1 and the VALID signal VAL to the target die.

The result storage buffer 311 may store the option selected in the SFR 307 and the information received from the pattern comparator 315. In some example embodiments, the result storage buffer 311 may store information about a clock option selected from among a plurality of particular (or, alternatively, predetermined) clock options.

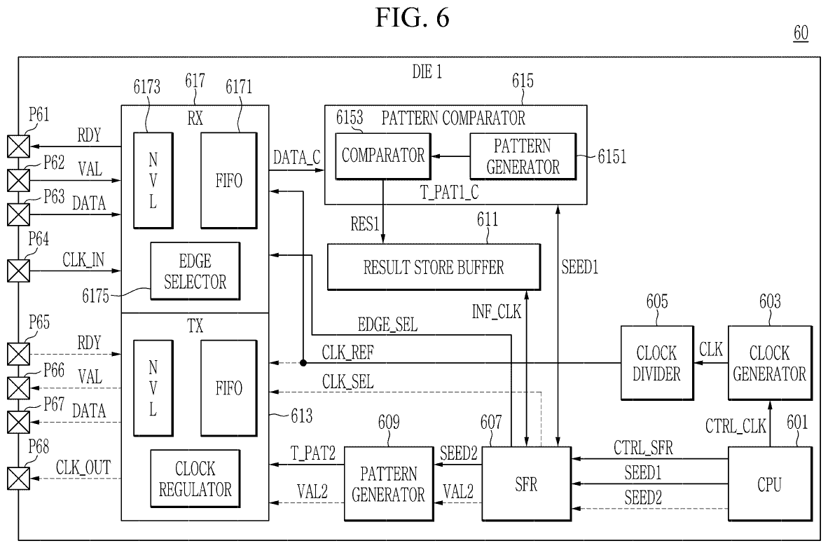

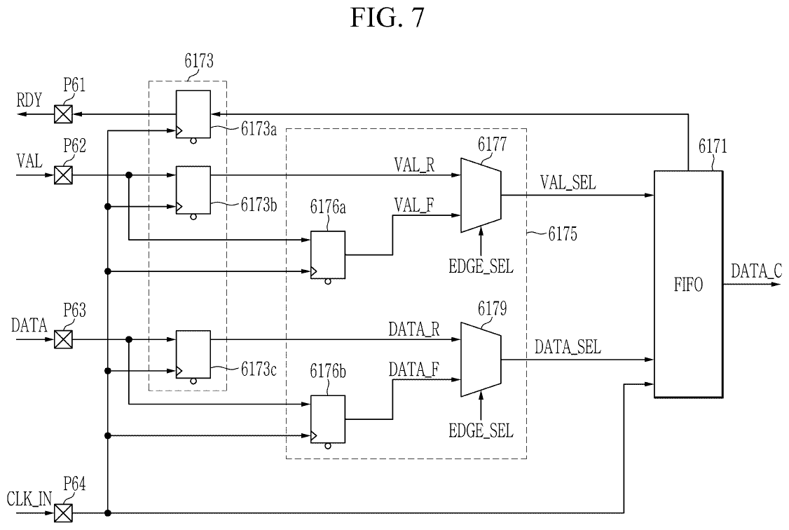

The receiver 317 may process the signal received from the target die and transmit it to the pattern comparator 315. The pattern comparator 315 may generate a comparison result based on the signal received from the receiver 317 and the signal received from the SFR 307. The pattern comparator 315 and the receiver 317 will be described later with reference to FIGS. 6 and 7.

The transmitter 313 may receive a test pattern T_PAT1, a VALID signal VAL, a clock selection signal CLK_SEL, and a reference clock signal CLK_REF. The transmitter 313 may generate an output clock signal CLK_OUT and a data signal DATA based on a test pattern T_PAT1, a VALID signal VAL, a clock selection signal CLK_SEL, and a reference clock signal CLK_REF. The transmitter 313 may output a plurality of signals—e.g., a VALID signal VAL, a data signal DATA, and an output clock signal CLK_OUT. Additionally, the transmitter 313 may receive a ready signal RDY. In some example embodiments, the transmitter 313 may output a VALID signal VAL based on the received ready signal RDY.

Referring to FIG. 4 together with FIG. 3, the transmitter 313 may include a FIFO circuit 3131, an NVL circuit 3133, and a clock regulator 3135.

The FIFO circuit 3131 receives a ready signal RDY, a test pattern T_PAT1, a VALID signal VAL, and a reference clock signal CLK_REF, and based on the ready signal RDY and the reference clock signal CLK_REF, a test signal T_SIG1 and VALID signal VAL can be output.

Specifically, the FIFO circuit 3131 may receive a ready signal RDY. The ready signal RDY may be a signal received from the target die through a plurality of NVL circuits 3133. The ready signal RDY may be a signal indicating whether the target die is ready to receive data from the reference die 30.

The FIFO circuit 3131 may transmit the VALID signal VAL received from the SFR 307 to a plurality of NVL circuits 3133.

In some example embodiments, the FIFO circuit 3131 may sample the test pattern T_PAT1 based on the reference clock signal CLK_REF. Specifically, the sampled test pattern T_PAT1 may include multiple bits. The FIFO circuit 3131 may include a register for storing a plurality of sampled bits. For example, a register can store data of size 320*64 bits. The FIFO circuit 3131 can output sampled bits sequentially from the first sampled bit to the last sampled bit. The FIFO circuit 3131 may transmit the test pattern T_PAT1 sampled based on the reference clock signal CLK_REF as the test signal T_SIG1 to the plurality of NVL circuits 3133.

The plurality of NVL circuits 3133 may be logic located around the TSV. Specifically, the NVL circuit 3133 may include a first NVL circuit 3133a, a second NVL circuit 3133b, and a third NVL circuit 3133c.

The first NVL circuit 3133a may receive a ready signal RDY from the target die. In some example embodiments, the first NVL circuit 3133a may include a flip-flop. Specifically, the first NVL circuit 3133a may latch the ready signal RDY to the output terminal in synchronization with an edge of the reference clock signal CLK_REF. In some example embodiments, the first NVL circuit 3133a may latch the ready signal RDY in synchronization with the rising edge of the reference clock signal CLK_REF. The first NVL circuit 3133a may transmit the latched ready signal RDY to the FIFO circuit 3131.

The second NVL circuit 3133b may receive the VALID signal VAL from the FIFO circuit 3131. In some example embodiments, the second NVL circuit 3133b may include a flip-flop. Specifically, the second NVL circuit 3133b may latch the VALID signal VAL to the output terminal in synchronization with the edge of the reference clock signal CLK_REF. In some example embodiments, the second NVL circuit 3133b may latch the VALID signal VAL in synchronization with the rising edge of the reference clock signal CLK_REF. In some example embodiments, the second NVL circuit 3133b may output a VALID signal VAL based on the ready signal RDY.

The third NVL circuit 3133c may receive the test signal T_SIG1 from the FIFO circuit 3131. In some example embodiments, the third NVL circuit 3133c may include a flip-flop. Specifically, the third NVL circuit 3133c may latch the test signal T_SIG1 to the output terminal in synchronization with the edge of the reference clock signal CLK_REF. In some example embodiments, the third NVL circuit 3133c may latch the test signal T_SIG1 in synchronization with the rising edge of the reference clock signal CLK_REF. The third NVL circuit 3133c may output the test signal T_SIG1 received from the FIFO circuit 3131 based on the reference clock CLK_REF.

The clock regulator 3135 can adjust the phase and timing of the reference clock signal CLK_REF to generate an output clock signal CLK_OUT. In some example embodiments, the clock regulator 3135 may adjust the phase and timing of the reference clock signal CLK_REF based on the clock selection signal CLK_SEL. Specifically, the clock regulator 3135 may include a plurality of phase shifters 3136a, 3136b, 3136c, and 3136d, a delay unit 3138, a first selector 3137, and a second selector 3139. The clock selection signal CLK_SEL may include a phase selection signal PHASE_SEL and a delay selection signal DELAY_SEL.

A plurality of phase shifters 3136a, 3136b, 3136c, and 3136d may shift the phase of the input reference clock signal CLK_REF by a separate, respective phase of first to fourth phases which may be different from each other. Specifically, the first phase shifter 3136a may generate the first clock shift signal CLK_PS1 by shifting the reference clock signal CLK_REF by the first phase. The second phase shifter 3136b may generate a second clock shift signal CLK_PS2 by shifting the reference clock signal CLK_REF by the second phase. The third phase shifter 3136c may generate a third clock shift signal CLK_PS3 by shifting the reference clock signal CLK_REF by the third phase. The fourth phase shifter 3136d may generate a fourth clock shift signal CLK_PS4 by shifting the reference clock signal CLK_REF by the fourth phase. In some example embodiments, the first phase may be 0, the second phase may be 90 degrees, the third phase may be 180 degrees, and the fourth phase may be 270 degrees.

The first selector 3137 is connected to each of the plurality of phase shifters 3136a, 3136b, 3136c, and 3136d and may receive and select one of the first clock shift signal CLK_PS1, the second clock shift signal CLK_PS2, the third clock shift signal CLK_PS3, or the fourth clock shift signal CLK_PS1 based on the phase selection signal PHASE_SEL, and the selected signal can be output as a phase shift signal CLK_SHIFT. The first selector 3137 may transmit the phase shift signal CLK_SHIFT to the delay unit 3138 and the second selector 3139.

The delay unit 3138 may generate a phase delay signal CLK_DELAY by delaying the phase shift signal CLK_SHIFT by a particular (or, alternatively, predetermined) amount (e.g., based on applying a particular, first delay to the phase shift signal CLK_SHIFT). The delay unit 3138 may include at least one buffer. The delay unit 3138 may transmit the phase delay signal CLK_DELAY to the second selector 3139.

The second selector 3139 may select one of the phase shift signal CLK_SHIFT or the phase delay signal CLK_DELAY based on the delay selection signal DELAY_SEL and output the selected signal as the output clock signal CLK_OUT.

Referring again to FIG. 3, the reference die 30 may include a plurality of pads P31, P32, P33, P34, P35, P36, P37, and P38. A plurality of pads (P31, P32, P33, and P34) may be connected to the TSV. The reference die 30 may output a plurality of signals through a plurality of pads (P31, P32, P33, and P34) and may also receive a plurality of signals through a plurality of pads (P35, P36, P37, and P38). Specifically, the first pad P31 may receive the ready signal RDY from the target die. The NVL 3133 may output a VALID signal VAL through the second pad P32. The NVL 3133 can output a data signal DATA through the third pad P33. The clock regulator 3135 may output an output clock signal CLK_OUT through the fourth pad P34.

Meanwhile, in FIG. 3, the reference die 30 is shown as including a CPU 301 and a clock generator 303, but the present inventive concepts are not limited thereto, and the CPU 301 and the clock generator 303 may be located outside of the reference die 30. Also, in FIG. 4, the reference die 30 is shown to output a data signal DATA through a single third pad P33, but the present inventive concepts are not limited thereto, and the reference die 30 can also output a data signal DATA through multiple pads.

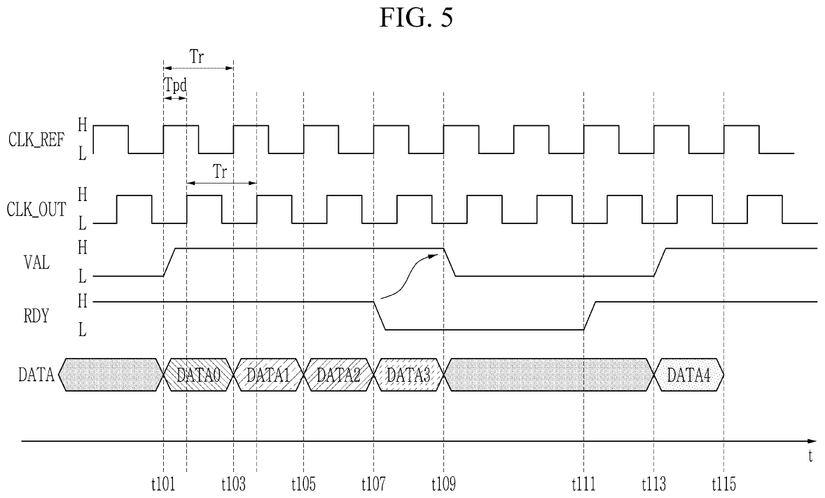

FIG. 5 is a timing diagram illustrating the operation timing of the reference die according to FIG. 3 according to some example embodiments.

First, the reference clock signal CLK_REF can be toggled with the reference period Tr.

The clock regulator 3135 may generate an output clock signal CLK_OUT based on the reference clock signal CLK_REF. In some example embodiments, the clock regulator 3135 may generate an output clock signal CLK_OUT delayed by a first period Tpd relative to the reference clock signal CLK_REF. The output clock signal CLK_OUT can be toggled with the reference period Tr. The configuration of the transmitter 313 (e.g., FIFO circuit 3131 and the NVL circuit 3133) may operate based on the reference clock signal CLK_REF.

First, at t101, the VALID signal VAL may transition from a low level (L) to a high level (H). At this time, the transmitter 313 may receive a high level (H) ready signal RDY. Accordingly, the transmitter 313 can output a data signal DATA. Specifically, the transmitter 313 may output the data signal DATA based on the reference clock signal CLK_REF. For example, during t101 to t103, the transmitter 313 may output a first data DATA0. During t103 to t105, the transmitter 313 may output a second data DATA1. During t105 to t107, the transmitter 313 may output a third data DATA2.

At t107, the transmitter 313 may receive a low level (L) ready signal RDY.

During t107 to t109, the transmitter 313 may output a fourth data DATA3.

At t109, the VALID signal VAL may transition to the low level (L). Specifically, the FIFO circuit 3131 of the transmitter 313 may generate a low level (L) VALID signal VAL as it receives (e.g., Based on the FIFO circuit 3131 receiving) a low level (L) ready signal RDY. While the VALID signal VAL maintains the low level (L) (e.g., based on the VALID signal VAL maintaining the low level (L)), the transmitter 313 may not output data.

At t111, the transmitter 313 may receive a high level (H) ready signal RDY.

At t113, the VALID signal VAL may transition to the high level (H). Specifically, the FIFO circuit 3131 of the transmitter 313 may generate a high level (H) VALID signal VAL as it receives (e.g., Based on the FIFO circuit 3131 receiving) the high level (H) ready signal RDY. The transmitter 313 can output data while the VALID signal VAL maintains the high level (H).

During t113 to t115, the transmitter 313 may output a fifth data DATA4.

In some example embodiments, the transmitter 313 may generate a plurality of output clock signals CLK_OUT having different phases by modulating the reference clock signal CLK_REF. The transmitter 313 may transmit a data signal DATA along with a plurality of output clock signals CLK_OUT. The receiver of the target die may capture the received data signal DATA based on the received output clock signal CLK_OUT. In some example embodiments, the receiver may capture the data signal DATA at the rising edge or the falling edge of the received output clock signal CLK_OUT.

The transmitter 313 may modulate the reference clock signal CLK_REF to generate various output clock signals CLK_OUT having various phases and delays, and transmit the generated output clock signal CLK_OUT with the data signal DATA. The target die may perform a comparison between the data captured by the receiver and the comparison pattern generated by the pattern comparator within the target die and generate a comparison result. Based on the comparison results (e.g., a determined difference between the captured data and the comparison pattern), the target die can detect that the output clock signal that captures the data signal DATA with the lowest error rate among the plurality of output clock signals CLK_OUT (e.g., a clock option corresponding with such an output clock signal and thus corresponding with the comparison result of comparing a comparison pattern with the data captured based on the output clock signal) is the optimal condition for transmitting data. In some example embodiments, the error rate may vary based on the number of bits of the test pattern generated by the pattern generator 309, clock options used to generate the output clock signal, etc. The target die may, based on such a detection, transmit data to the reference die 30 to instruct the reference die 30 (e.g., CPU 301) to implement at least the determined clock option (indicated by the clock information INF_CLK) corresponding to the optimal output clock signal capturing the data signal DATA with the lowest error rate for future transmissions of data from the reference die 30 to the target die, for example based on transmitting data indicating the optimal clock option to the reference die 30 in a data signal DATA transmission to cause the CPU 301 of the reference die 30 to transmit a SFR control signal CTRL_SFR that causes the SFR 307 to select the clock option indicated by the clock information INF_CLK for future generation of at least the output clock signal CLK_OUT. As a result, the semiconductor device may be configured to reduce, minimize, or prevent errors in data transmissions from the reference die 30 to the target die via one or more TSVs, and thus improving the functionality of the semiconductor device. The target die may detect that the output clock signal that captures the data signal DATA with the lowest error rate is the optimal transmission signal. The target die may receive a data signal (DATA) based on the optimal transmission signal.

FIG. 6 is a diagram illustrating a target die according to some example embodiments. FIG. 7 is a diagram illustrating in detail a configuration of the target die according to FIG. 6 according to some example embodiments. In some example embodiments, the target die 60 may include or may be included in the first die 21 and/or the second die 23 shown in FIG. 2.

The target die 60 includes a CPU 601, a clock generator 603, an SFR 607, a pattern generator 609, a result storage buffer 611, a transmitter 613, a pattern comparator 615, and a receiver 617, and may include a plurality of pads (P61, P62, P63, P64, P65, P66, P67, P68, P69).

The CPU 601 may determine a seed for generating the comparison result RES1.

The CPU 601 may generate the clock control signal CTRL_CLK to control the clock generator 603. The clock control signal CTRL_CLK may be a signal that controls the clock generator 603 to generate the clock signal CLK. The CPU 601 may transmit the clock control signal CTRL_CLK to the clock generator 603.

The CPU 601 may generate an SFR control signal CTRL_SFR to control the SFR 607. The SFR control signal CTRL_SFR may be a signal for selecting one of a plurality of options stored in the SFR 607. The CPU 601 may transmit the SFR control signal CTRL_SFR and the first seed SEED1 to the SFR 607.

The clock generator 603 may generate the clock signal CLK. In some example embodiments, the clock generator 603 may generate the clock signal CLK based on the clock control signal CTRL_CLK. The clock generator 603 may transmit a clock signal CLK to the clock divider 605.

The clock divider 605 may receive the clock signal CLK from the clock generator 603 and divide the clock signal CLK to generate a reference clock signal CLK_REF. In some example embodiments, the clock divider 605 may divide the clock signal CLK by a constant phase difference to generate the reference clock signal CLK_REF. For example, the clock divider 605 may divide the clock signal CLK by two to generate the reference clock signal CLK_REF. The clock divider 605 may transmit the reference clock signal CLK_REF to the receiver 617.

The SFR 607 may store edge types that can determine data reception characteristics of the receiver 617. The edge types may include rising edges, falling edges, etc.

The SFR 607 may generate an edge selection signal EDGE_SEL based on the SFR control signal CTRL_SFR. The edge selection signal EDGE_SEL may be a signal indicating an option for data capture. The SFR 607 may transmit the edge selection signal EDGE_SEL to the receiver 617. That is, the SFR 607 may transmit to the receiver 617 the edge selection signal EDGE_SEL generated based on an edge type selected based on the SFR control signal CTRL_SFR among edge types.

The SFR 607 may transmit the first seed SEED1 to the pattern comparator 615.

The pattern generator 609 may generate a test pattern based on the seed received from the SFR 607. The pattern generator 609 may transmit the generated test pattern to the transmitter 613.

The result storage buffer 611 can receive clock information INF_CLK from the SFR 607. The clock information INF_CLK may include the clock option of the transmitter and the edge type of the receiver 617. Additionally, the result storage buffer 611 may receive the comparison result RES1 from the pattern comparator 615. When the comparison result RES1 is a result of a comparison between a comparison pattern T_PAT1_C as noted below and data DATA_C that is captured based on an output clock signal CLK_OUT that is received at the target die 60 as an input clock signal CLK_IN, the comparison result RES1 may be understood to correspond to the clock information INF_CLK. The result storage buffer 611 may store the received clock information INF_CLK and the comparison result RES1 corresponding to the clock information INF_CLK.

The transmitter 613 may receive a test pattern from the pattern generator 609. The transmitter 613 may receive a reference clock signal CLK_REF from the clock divider 605. Additionally, the transmitter 613 may receive a clock selection signal CLK_SEL from the SFR 607. The transmitter 613 may output a test pattern as a data signal based on the reference clock signal CLK_REF and the clock selection signal CLK_SEL. The content described with reference to FIGS. 3 and 4 may be similarly applied to the pattern generator 609 and transmitter 613.

The pattern comparator 615 may receive the first seed SEED1 from the SFR 607. Additionally, the pattern comparator 615 may receive data DATA_C from the receiver 617. Specifically, the pattern comparator 615 may include a pattern generator 6151 and a comparator 6153.

The pattern generator 6151 may generate a comparison pattern T_PAT1_C based on the first seed SEED1. In some example embodiments, the pattern generator 6151 may generate a comparison pattern T_PAT1_C based on the LFSR algorithm, which may be the same LFSR algorithm used by the pattern generator 309 of the reference die 30 to generate the test pattern T_PAT1 based on the first seed SEED1. The pattern generator 6151 may transmit the generated comparison pattern T_PAT1_C to the comparator 6153.

The comparator 6153 may compare (e.g., determine a difference between) the data DATA_C and comparison pattern T_PAT1_C and generate a comparison result RES1 (which may include information indicating the difference). In some example embodiments, the comparator 6153 may include an XOR logic circuit. The comparator 6153 may transmit the generated comparison result RES1 to the result storage buffer 611. In some example embodiments, when the comparison pattern T_PAT1_C and the data DATA_C have different bits, the comparison result RES1 may include information about the positions of the different bits.

The receiver 617 can receive a VALID signal VAL, a data signal DATA, an input clock signal CLK_IN, a reference clock signal CLK_REF, and an edge selection signal EDGE_SEL. The receiver 617 may generate data DATA_C based on the data signal DATA, the input clock signal CLK_IN, and the edge selection signal EDGE_SEL. The receiver 617 may output a ready signal RDY.

A plurality of pads (P61, P62, P63, P64, P65, P66, P67, P68) may be connected to the TSV. The target die 60 may receive a plurality of signals through a plurality of pads (P61, P62, P63, and P64), and may output a plurality of signals through a plurality of pads (P65, P66, P67, and P68). Specifically, the NVL 6173 may output a ready signal RDY to the reference die through the first pad P61. The NVL 6173 can receive the VALID signal VAL through the second pad P62. The NVL 6173 can receive the data signal DATA through the third pad P63. The FIFO circuit 6171 can receive the input clock signal CLK_IN through the fourth pad P64. The input clock signal CLK_IN may be the output clock signal CLK_OUT that is output by the reference die 30 as shown in FIGS. 3 and 4, such that the target die 60 may receive the output clock signal CLK_OUT as the input clock signal CLK_IN.

Referring to FIG. 7 together with FIG. 6, the receiver 617 may include a FIFO circuit 6171, a plurality of NVL circuits 6173, and an edge selector 6175.

A plurality of NVL circuits 6173 may be logic located around the TSV. Specifically, the plurality of NVL circuits 6173 may include a first NVL circuit 6173a, a second NVL circuit 6173b, and a third NVL circuit 6173c.

The first NVL circuit 6173a may output a ready signal RDY to the reference die (e.g., reference die 30 shown in FIGS. 3-4). In some example embodiments, the first NVL circuit 6173a may include a rising edge flip-flop. Specifically, the first NVL circuit 6173a may latch the ready signal RDY to the output terminal in synchronization with the edge of the input clock signal CLK_IN. In some example embodiments, the first NVL circuit 6173a may capture (e.g., may latch) the ready signal RDY in synchronization with the rising edge of the input clock signal CLK_IN. The first NVL circuit 6173a may output the latched ready signal RDY to the first pad P61.

The second NVL circuit 6173b may receive the VALID signal VAL from the second pad P62. In some example embodiments, the second NVL circuit 6173b may include a flip-flop. Specifically, the second NVL circuit 6173b may latch the VALID signal VAL to the output terminal in synchronization with the edge of the input clock signal CLK_IN. In some example embodiments, the second NVL circuit 6173b may capture (e.g., may latch) the VALID signal VAL in synchronization with the rising edge of the input clock signal CLK_IN. The second NVL circuit 6173b may output the latched VALID signal VAL in synchronization with the rising edge of the input clock signal CLK_IN to the edge selector 6175 as the first VALID signal VAL_R.

The third NVL circuit 6173c may receive the data signal DATA from the third pad P63. In some example embodiments, the third NVL circuit 6173c may include a flip-flop. Specifically, the third NVL circuit 6173c may latch the data signal DATA to the output terminal in synchronization with the edge of the input clock signal CLK_IN. In some example embodiments, the third NVL circuit 6173c may capture (e.g., may latch) the data signal DATA in synchronization with the rising edge of the input clock signal CLK_IN. The third NVL circuit 6173c may output the latched data signal DATA in synchronization with the rising edge of the input clock signal CLK_IN to the edge selector 6175 as the first data signal DATA_R.

The edge selector 6175 may include a first flip-flop 6176a, a second flip-flop 6176b, a first selector 6177, and a second selector 6179.

The first flip-flop 6176a may receive the VALID signal VAL from the second pad P62. In some example embodiments, the first flip-flop 6176a may be a falling edge flip-flop. The first flip-flop 6176a may capture (e.g., may latch) the VALID signal VAL at the output terminal in synchronization with the falling edge of the input clock signal CLK_IN. The first flip-flop 6176a may output the latched VALID signal VAL in synchronization with the falling edge of the input clock signal CLK_IN to the first selector 6177 as the second VALID signal VAL_F.

The second flip-flop 6176b may receive the data signal DATA from the third pad P63. In some example embodiments, the second flip-flop 6176b may be a falling edge flip-flop. The second flip-flop 6176b can capture (e.g., may latch) the data signal DATA to the output terminal in synchronization with the falling edge of the input clock signal CLK_IN. The second flip-flop 6176b may output the latched data signal DATA in synchronization with the falling edge of the input clock signal CLK_IN to the second selector 6179 as the second data signal DATA_F.

The first selector 6177 may receive a first VALID signal VAL_R from the second NVL circuit 6173b and a second VALID signal VAL_F from the first flip-flop 6176a. The first selector 6177 selects one of the first VALID signal VAL_R and the second VALID signal VAL_F based on the edge selection signal EDGE_SEL, and outputs the selected signal as the selection VALID signal VAL_SEL. The first selector 6177 may output a selection VALID signal VAL_SEL to the FIFO circuit 6171.

The second selector 6179 may receive a first data signal DATA_R from the third NVL circuit 6173c and a second data signal DATA_F from the second flip-flop 6176b. The second selector 6179 selects one of the first data signal DATA_R and the second data signal DATA_F based on the edge selection signal EDGE_SEL, and outputs the selected signal as the selection data signal DATA_SEL. The second selector 6179 may output a selection data signal DATA_SEL to the FIFO circuit 6171.

The FIFO circuit 6171 can receive a selection VALID signal VAL_SEL from the first selector 6177, a selection data signal DATA_SEL from the second selector 6179, and an input clock signal CLK_IN from the fourth pad P64.

In some example embodiments, the FIFO circuit 6171 may sample the selection data signal DATA_SEL based on the input clock signal CLK_IN. Specifically, the sampled selection data signal DATA_SEL may include multiple bits. The FIFO circuit 6171 may include a register for storing a plurality of sampled bits. For example, a register can store data of size 320*64. The FIFO circuit 6171 can output sampled bits sequentially from the first sampled bit to the last sampled bit. The FIFO circuit 6171 may transmit the sampled selection data signal DATA_SEL based on the reference clock signal CLK_REF as data DATA_C to the pattern comparator 615.

The FIFO circuit 6171 can generate a ready signal RDY. Specifically, the FIFO circuit 6171 generates a ready signal RDY at an enable level when the target die 60 is ready to receive the data signal DATA from the reference die, and a disable-level ready signal RDY when it is not ready to receive the data signal DATA. In some example embodiments, the FIFO circuit 6171 may generate a ready signal RDY at a disable level when the capacity of an internal register is full. For example, the FIFO circuit 6171 may generate a ready signal RDY at a disable level before the register is full to account for the delay when receiving the data signal DATA from the reference die. In some example embodiments, the FIFO circuit 6171 may generate the ready signal RDY at a disable level until the pattern generator 6151 of the target die 60 generates the comparison pattern T_PAT1_C. The FIFO circuit 6171 may output the ready signal RDY to the first pad P61.

In FIG. 6, the FIFO circuit in the transmitter 613 is shown separately from the FIFO circuit 6171 in the receiver 617, but the present inventive concepts are not limited thereto, and the FIFO circuit in the transmitter 613 and the FIFO circuit 6171 in the receiver 617 may have the same configuration.

Meanwhile, in FIG. 6, the target die 60 is shown as including a CPU 601 and a clock generator 603, but the present inventive concepts are not limited thereto, and the CPU 601 and the clock generator 603 may be located outside of the target die 60. Also, in FIG. 6, the target die 60 is shown to receive a data signal DATA through a single third pad P63, but the present inventive concepts are not limited to this, and the target die 60 may also receive a data signal DATA through a plurality of pads.

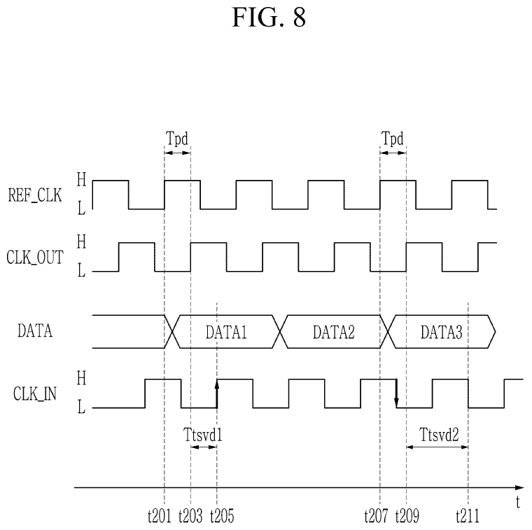

FIG. 8 is a timing diagram illustrating the operation timing of a target die according to some example embodiments. Specifically, FIG. 8 shows the timing of data capture according to the edge selection signal EDGE_SEL.

The reference die may output the reference clock signal CLK_REF as the output clock signal CLK_OUT to the target die 60 through a particular (or, alternatively, predetermined) phase shift and delay. The output clock signal CLK_OUT may be delayed by a first period Tpd relative to the reference clock signal CLK_REF. On the other hand, while being transferred from the reference die (e.g., reference die 30) to the target die 60, there may be a certain amount of delay due to TSV IO delay. Accordingly, the output clock signal CLK_OUT can be received as an input clock signal CLK_IN to the target die 60.

First, at t201, the reference clock signal CLK_REF may transition to high level (H).

At t203, the output clock signal CLK_OUT may transition to high level (H).

At t205, the input clock signal CLK_IN may transition to high level (H). If the receiver 617 captures the data signal DATA at the rising edge according to the edge selection signal EDGE_SEL, the receiver 617 may capture the data signal DATA1 at t205. At this time, the input clock signal CLK_IN may be delayed for a second period Ttsvd1 relative to the output clock signal CLK_OUT and then input to the target die 60. Afterwards, the reference clock signal CLK_REF may transition to high level (H) at t207.

At t209, the output clock signal CLK_OUT may transition to high level (H).

At t211, the input clock signal CLK_IN may transition to low level (L). If the receiver 617 captures the data signal DATA at the falling edge according to the edge selection signal EDGE_SEL, the receiver 617 may capture the data signal DATA3 at t211. At this time, the input clock signal CLK_IN may be delayed for a third period Ttsvd2 relative to the output clock signal CLK_OUT and then input to the target die 60.

As shown in FIG. 8, when the receiver 617 captures the received data signal DATA, the error rate may be affected depending on the rising edge or falling edge. The receiver 617 may transmit the captured data signal DATA as data DATA_C to the pattern comparator 615.

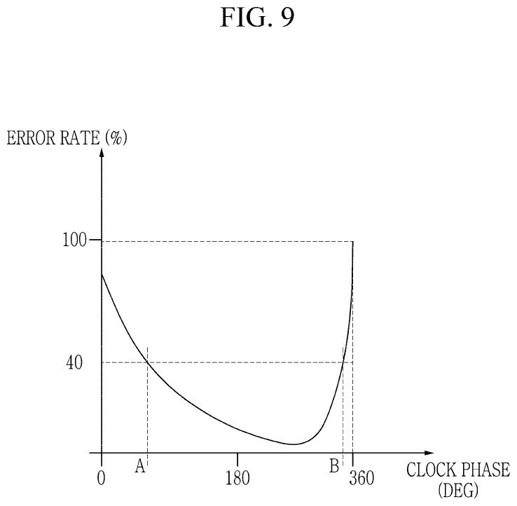

FIG. 9 is a graph illustrating the change in error rate according to some example embodiments.

Specifically, FIG. 9 is a graph illustrating the error rate of the data signal DATA received from the target die 60 according to the phase difference between the reference clock signal CLK_REF and the input clock signal CLK_IN.

When the reference die (30 in FIG. 3) transmits a data signal DATA based on the input clock signal CLK_IN, which has the same phase as the reference clock signal CLK_REF, to the target die 60, it may have a high error rate due to the TSV delay (Ttsvd1 in FIG. 8).

As the phase difference between the reference clock signal CLK_REF and the input clock signal CLK_IN increases, the error rate of the data signal DATA may decrease to a certain extent and then increase. The target die 60 may set an acceptable reference error rate of the data signal DATA and determine a phase difference that causes the data signal DATA to have an error rate smaller than the reference error rate. For example, as shown in FIG. 9, the target die 60 can set an error rate of 40% or less as the reference error rate, and the reference die (30 in FIG. 3) can select an option to control so that the reference clock signal CLK_REF and the input clock signal CLK_IN have a phase difference between A degrees and B degrees. Additionally, the target die 60 may predict the TSV delay time between the reference die (30 in FIG. 3) and the target die 60 based on the determined phase difference.

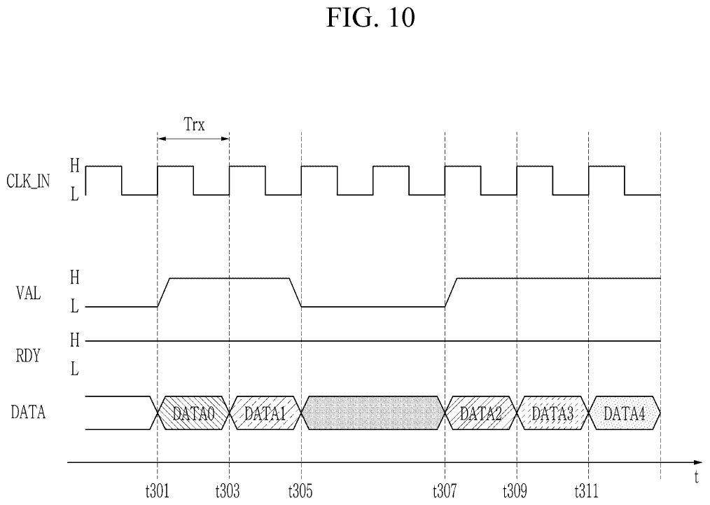

FIG. 10 is a timing diagram illustrating the operation timing of a target die according to some example embodiments. Specifically, FIG. 9 shows the operation of the target die 60 according to the VALID signal VAL.

First, the input clock signal CLK_IN can be toggled in the first period Trx. The receiver (617 in FIG. 6) may determine whether to store the data signal DATA based on the VALID signal VAL. In FIG. 9, for convenience of explanation, it is assumed that the enable level of the VALID signal VAL and the enable level of the ready signal RDY are high level (H).

At t301, the input clock signal CLK_IN may transition to high level (H), and the VALID signal VAL may transition to high level (H). The ready signal RDY can remain at high level (H). The high level (H) ready signal RDY may be a signal indicating whether the target die 60 is ready to receive data.

The receiver 617 may store the data signal DATA0 as the VALID signal VAL transitions to high level (H).

Afterwards, since the VALID signal VAL remains at high level (H) at t303, the receiver 617 can store the data signal DATA1.

At t305, the VALID signal VAL may transition from high level (H) to low level (L). Accordingly, the receiver 617 may not store the data signal. While the VALID signal VAL remains at low level (L) (t305-t307), the receiver 617 may not store the data signal.

At t307, the VALID signal VAL may transition from a low level (L) to a high level (H). Accordingly, the receiver 617 can store the data signal DATA2 again. Afterwards, while the VALID signal VAL remains at high level (H), the receiver 617 can store the received data signals (DATA3 and DATA4) at t309 and t311, respectively.

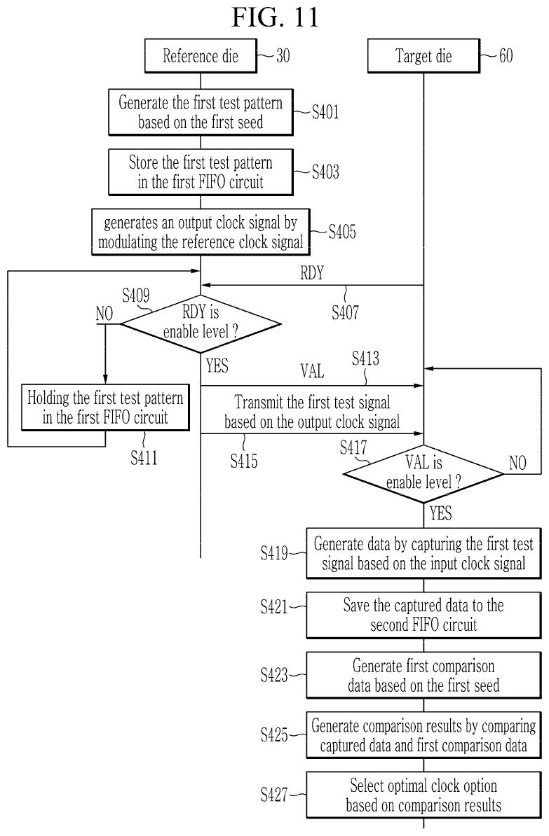

FIG. 11 is a diagram illustrating a method of operating a semiconductor device according to some example embodiments.

First, the reference die (30 in FIG. 3) generates a first test pattern based on the first seed at S401.

The reference die 30 stores the first test pattern in the first FIFO circuit at S403.

The reference die 30 generates an output clock signal by modulating the reference clock signal at S405. In some example embodiments, the reference die 30 may generate an output clock signal by applying a particular (or, alternatively, predetermined) phase and delay to the reference clock signal.

The reference die 30 receives a ready signal RDY from the target die (60 in FIG. 6) at S407.

The reference die 30 determines whether the ready signal RDY is at an enable level at S409.

When the reference die 30 determines that the ready signal RDY is not at an enable level (S409=NO), the reference die 30 holds the first test pattern in the first FIFO circuit at S411. Thereafter, the reference die 30 may perform the step S407 of receiving the ready signal RDY again. If the reference die 30 determines that the ready signal RDY is at an enable level (S409=YES), the reference die 30 may transmit a VALID signal at S413 to the target die 60. Additionally, the reference die 30 transmits the first test signal to the target die 60 based on the output clock signal at S415. Specifically, the reference die 30 may transmit the first test pattern stored in the first FIFO circuit to the target die 60 as a first test signal based on the output clock signal. In FIG. 9, the reference die 30 is shown as performing the steps of transmitting the VALID signal at S413 and transmitting the first test signal at S415, but the present inventive concepts are not limited thereto and the reference die 30 is The steps of transmitting the VALID signal S413 and transmitting the first test signal at S415 may be performed simultaneously.

The target die 60 determines at S417 whether the received VALID signal VAL is at an enable level.

If the target die 60 determines at S417 that the VALID signal VAL is not at an enable level (S417=NO), the step of receiving the VALID signal VAL can be performed again.

When the target die 60 determines that the VALID signal VAL is at an enable level (S417=YES), the target die 60 captures the first test signal based on the input clock signal and generates data at S419. Here, the input clock signal may be an output clock signal that reaches the target die 60 by passing through a TSV or the like from the reference die 30. In some example embodiments, the target die 60 may capture the first test signal based on the rising edge or falling edge of the input clock signal.

The target die 60 stores the captured data in the second FIFO circuit at S421.

The target die 60 generates first comparison data based on the first seed at S423. In some example embodiments, the target die 60 may generate comparison data based on the seed from which the reference die 30 is used to generate the first test pattern.

The target die 60 compares the captured data stored in the second FIFO circuit and the first comparison data to generate a comparison result at S425.

The target die 60 selects the optimal clock option based on the comparison result at S427, for example selecting an optimal clock option that has a lowest error rate (e.g., a smallest difference between captured data and first comparison data). The target die 60 may transmit a signal to the reference die 30 to implement the selected optimal clock option (e.g., via the CPU 301 controlling at least the SFR 307 through CTRL_SFR) for future transmissions of data to the target die 60, to thereby reduce, minimize, or prevent errors in data transmissions from the reference die 30 to the target die 60 via one or more TSVs due to delays, phase changes, etc. The target die 60 may store the selected clock option (e.g., in the result storage buffer 611) and transmit same to the reference die 30 in a data signal DATA transmission. As a result, the functionality of a semiconductor device including the target die 60 and the reference die 30 (e.g., the reduction, minimization, or prevention of errors in data transmitted between the reference die 30 and the target die 60 through one or more TSVs) may be improved, and thus the reliability of the semiconductor device may be improved.

For example, the reference die 30 may transmit the first test signal to the target die 60 multiple times along with an output clock signal modulated according to each of a plurality of clock options.

In some example embodiments, the reference die 30 may transmit the first test signal along with the first output clock signal according to the first clock option to the target die 60 a particular (or, alternatively, predetermined) number of times. For example, the reference die 30 may transmit the first test signal to the target die 60 approximately 100 to 1,000 times. The target die 60 generates comparison results for each case when the first test signal according to the first output clock signal is captured with a rising edge and when the first test signal according to the first output clock signal is captured with a falling edge. The target die 60 may determine the clock option and edge type with the lowest error rate (e.g., the clock option and edge type corresponding to output clock signal CLK_OUT used to capture data having a smallest difference with the first comparison data as indicated by a comparison result) among the plurality of comparison results. In this regard, the target die 60 determines the edge type corresponding to the first output clock signal. The reference die 30 may transmit the first test signal along with the second output clock signal according to the second clock option to the target die 60 a particular (or, alternatively, predetermined) number of times. The target die 60 may generate comparison results for each case when the second test signal according to the second output clock signal is captured with a rising edge and when the second output clock signal is captured with a falling edge, respectively. The target die may determine a plurality of output clock signals modulated according to each of the plurality of clock options, and a corresponding edge type for each of the plurality of output clock signals. The corresponding edge type may be an edge type having the lowest error rate for each of the plurality of output clock signals. The target die may determine a clock option and edge type having the lowest error rate among the plurality of output clock signals and corresponding edge types. Subsequently, the target die may capture signals (e.g., commands, data) received from the outside via the transfer memory chip (CHIP_INT in FIG. 1) based on the determined clock option and edge type. The target die 60 may, based on such a detection, transmit data to the reference die 30 to instruct the reference die 30 (e.g., CPU 301) to implement at least the determined clock option (indicated by the clock information INF_CLK used to arrive at the comparison result indicating the lowest error rate) corresponding to the optimal output clock signal capturing the data signal DATA with the lowest error rate for future transmissions of data from the reference die 30 to the target die 60 (e.g., based on information indicating at least the optimal clock option to the reference die 30 in a data signal DATA transmission to cause the CPU 301 of the reference die 30 to transmit a SFR control signal CTRL_SFR that causes the SFR 307 to select the clock option indicated by the clock information INF_CLK for future generation of at least the output clock signal CLK_OUT). The target die 60 may cause the receiver 617 to implement an edge type corresponding to the lowest error rate. As a result, the semiconductor device may be configured to reduce, minimize, or prevent errors in data transmissions from the reference die 30 to the target die 60 via one or more TSVs, and thus improving the functionality of the semiconductor device.

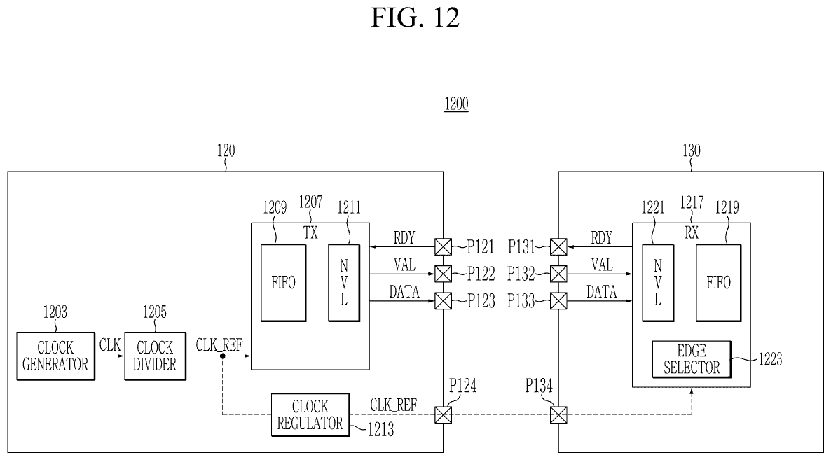

FIG. 12 is a diagram illustrating a configuration of a semiconductor device according to some example embodiments.

A semiconductor device 1200 may include a first die 120 and a second die 130.

The first die 120 may include the clock generator 1203, the clock divider 1205, the transmitter 1207, the clock regulator 1213, and a plurality of pads (P121, P122, P123, and P124).

The clock generator 1203 may generate a clock signal CLK.

The clock generator 1203 may transmit the clock signal CLK to the clock divider 1205.

The clock divider 1205 may receive the clock signal CLK from the clock generator 1203 and divide the clock signal CLK to generate the reference clock signal CLK_REF. The clock divider 1205 may transmit the reference clock signal CLK_REF to the transmitter 1207 and the clock regulator 1213.

The transmitter 1207 may include a FIFO circuit 1209 and an NVL circuit 1211.

The transmitter 1207 may receive a VALID signal VAL and a reference clock signal CLK_REF. The FIFO circuit 1209 and the NVL circuit 1211 may operate based on the reference clock signal CLK_REF. In some example embodiments, the transmitter 1207 may output a VALID signal VAL based on the received ready signal RDY.

The clock regulator 1213 may adjust the phase and timing of the reference clock signal CLK_REF. In some example embodiments, the clock regulator 1213 may adjust the phase and timing of the reference clock signal CLK_REF. In some example embodiments, the clock regulator 1213 may transmit the reference clock signal CLK_REF directly to the second die 130 through the fourth pad P124. Accordingly, since the reference clock signal CLK_REF can be immediately transmitted to the second die 130, additional TSV delay may not occur.

The second die 130 may include a receiver 1217 and a plurality of pads (P131, P132, P133, and P134). The receiver 1217 may include a FIFO circuit 1219, a plurality of NVL circuits 1221, and an edge selector 1223.

The receiver 1217 may operate based on the reference clock signal CLK_REF received from the first die 120.

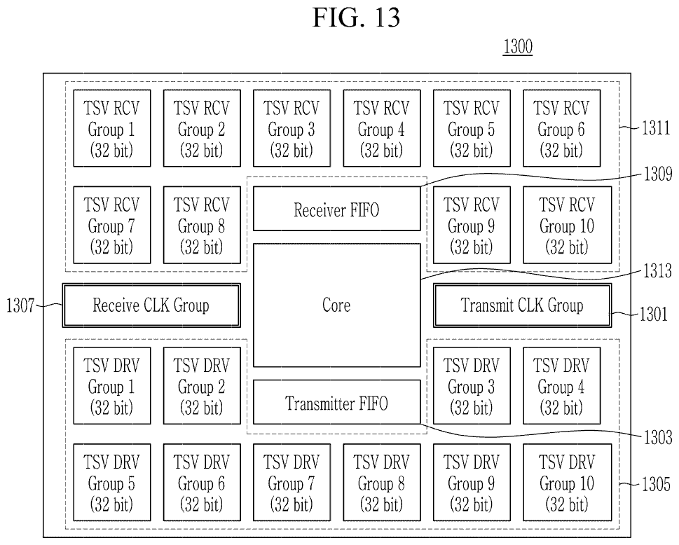

FIG. 13 is a plan view illustrating the inside of a memory die according to some example embodiments.

The memory die 1300 includes an area 1301 for transmitting a clock signal, an area 1303 where the FIFO circuit of the transmitter is located, a TSV area 1305 of the transmitter, an area 1307 for receiving a clock signal, an area 1309 where the FIFO circuit is located, a TSV area 1311 of the receiver, and a core area 1313. The receiving area of the memory die 1300 may be placed at the top of the memory die 1300, and the transmission area of the memory die 1300 may be placed at the bottom of the memory die 1300. Meanwhile, another memory die may have a reception area located at the bottom and a transmission area at the top corresponding to the memory die 1300.

Although not shown in FIG. 13, the NVL area may be located around (e.g., may at least partially surround) the TSV area 1305 and TSV area 1311.

As shown in FIG. 13, the TSV area 1305 and TSV area 1311 are disposed in areas where the internal functional circuits 1301, 1303, 1307, 1309, and 1313 of the memory die 1300 are not disposed. In FIG. 13, the through electrodes are shown to be clustered and arranged in a certain area of the memory die 1300, but the present inventive concepts are not limited thereto and they may be distributed and arranged throughout the memory die 1300.

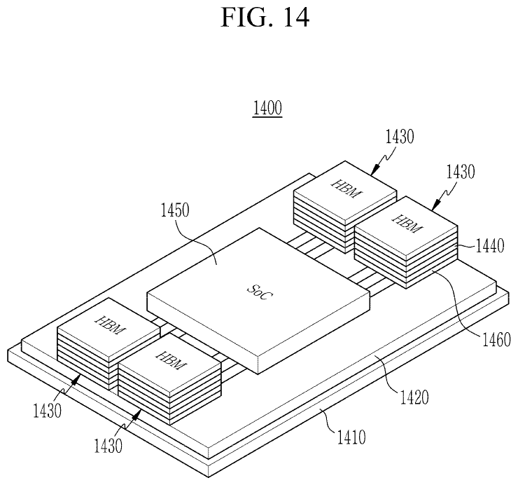

FIG. 14 is a diagram illustrating a semiconductor device according to some example embodiments.

Referring to FIG. 14, the semiconductor device 1400 may be a memory module that includes at least one stacked semiconductor chip 1430 and a system-on-chip SOC 1450 mounted on a package substrate 1410, such as a printed circuit board.

An interposer 1420 may be optionally further provided on the package substrate 1410. The stacked semiconductor chip 1430 may be formed as a chip-on-chip (CoC). The stacked semiconductor chip 1430 may include at least one memory chip 1440 stacked on a buffer chip 1460 such as a logic chip. The buffer chip 1460 and at least one memory chip 1440 may be connected to each other by means of a through silicon via TSV. In some example embodiments, the buffer chip 1460 and at least one memory chip 1440 may include the test circuit described with reference to FIGS. 1 to 13. Accordingly, the semiconductor device 1400 according to some example embodiments may determine a clock option by considering delays when transmitting signals between semiconductor dies. Optimal conditions can be determined to have a low error rate during data transmission. In some example embodiments, the stacked semiconductor chip 1430 may be, for example, high-bandwidth memory (HBM) of 500 GB/sec to 1 TB/sec or more.

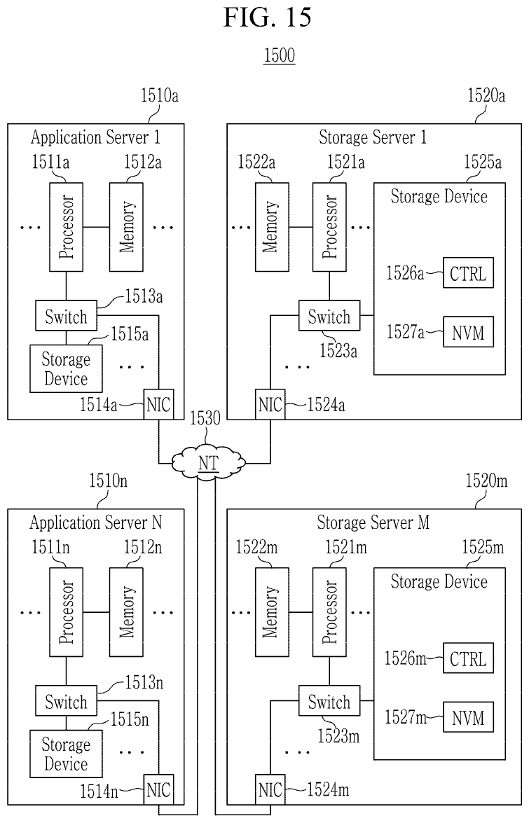

FIG. 15 is a block diagram illustrating a data center according to some example embodiments.

Referring to FIG. 15, the data center 1500 is a facility that collects various types of data and provides services, and may also be referred to as a data storage center. The data center 1500 may be a system for operating a search engine and database, or may be a computing system used in companies such as banks or government agencies. The data center 1500 may include application servers 1510a, . . . , 1510n and storage servers 1520a, . . . , 1520m, where “n” and “m” may each independently be any positive integer. The number (quantity) of application servers 1510a, . . . , 1510n and the number (quantity) of storage servers 1520a, . . . , 1520m may be selected in various ways depending on the example embodiment, and the number (quantity) of application servers 1510a, . . . , 1510n and the number of storage servers 1520a, . . . , 1520m may be different.

The application server 1510 or the storage server 1520 may include at least one of processors 1511 and 1521 and memories 1512 and 1522. Taking the storage server 1520 as an example, the processor 1521 can control the overall operation of the storage server 1520, accesses the memory 1522, and executes instructions and/or data loaded into the memory 1522. The memory 1522 may be double data rate synchronous DRAM (DDR SDRAM), high-bandwidth memory (HBM), hybrid memory cube (HMC), dual in-line memory module (DIMM), optane DIMM, or non-volatile DIMM (NVMDIMM). Depending on the example embodiment, the number of processors 1521 and memories 1522 included in the storage server 1520 may be selected in various ways. In some example embodiments, the processor 1521 and the memory 1522 may provide a processor-memory pair. In some example embodiments, the number of processors 1521 and memories 1522 may be different. The processor 1521 may include a single core processor or a multi-core processor. The above description of the storage server 1520 may be similarly applied to the application server 1510. Depending on the example embodiment, the application server 1510 may not include the storage device 1515. The storage server 1520 may include at least one storage device 1525. The number of storage devices 1525 included in the storage server 1520 may be selected in various ways depending on the example embodiment.

The application servers 1510a, . . . , 1510n and storage servers 1520a, . . . , 1520m may communicate with each other through a network 1530. The network 1530 may be implemented using fiber channel (FC) or ethernet. At this time, FC is a medium used for relatively high-speed data transmission, and an optical switch that provides high performance/high availability can be used. Depending on the access method of the network 1530, the storage servers 1520a, . . . , 1520m may provide file storage, block storage, or object storage.

In some example embodiments, the network 1530 may be a storage-only network, such as a storage area network (SAN). For example, the SAN may be an FC-SAN that uses an FC network and is implemented according to the FC protocol (FCP). In another example, the SAN may be an IP-SAN that utilizes a TCP/IP network and is implemented according to the iSCSI (SCSI over TCP/IP or Internet SCSI) protocol. In other embodiments, the network 1530 may be a general network, such as a TCP/IP network. For example, the network 1530 may be implemented according to protocols such as FC over ethernet (FCOE), network-attached storage (NAS), and NVMe over fabrics (NVMe-oF).

Hereinafter, the description will focus on the application server 1510 and the storage server 1520. The description of the application server 1510 may also be applied to other application servers 1510n, and the description of the storage server 1520 may also be applied to other storage servers 1520m.

The application server 1510 may store data requested by a user or client to be stored in one of the storage servers 1520a, . . . , 1520m through the network 1530. Additionally, the application server 1510 may obtain data requested to be read by a user or client from one of the storage servers 1520a, . . . , 1520m through the network 1530. For example, the application server 1510 may be implemented as a web server or a database management system (DBMS).

The application server 1510 can access the memory 1512n or the storage device 1515n contained in another application server 1510n over the network 1530, or can access the memory 1522a, . . . , 1522m or the storage device 1525a, . . . , 1525m contained in the storage server 1520a, . . . , 1520m over the network 1530. Accordingly, the application server 1510 can perform various operations on data stored in the application servers 1510a, . . . , 1510n and/or the storage servers 1520a, . . . , 1520m. For example, the application server 1510 may execute a command to move or copy data between the application servers 1510a, . . . , 1510n and/or the storage servers 1520a, . . . , 1520m. At this time, the data flows from the storage devices 1525a, . . . , 1525m of the storage servers 1520a, . . . , 1520m through the memories 1522a, . . . , 1522m of the storage servers 1520a, . . . , 1520m, or it can be immediately moved to the memories 1512a, . . . , 1512n of the application servers 1510a, . . . , 1510n. Data moving through the network 1530 may be encrypted data for security or privacy.

The storage server 1520 may further include a switch 1523 and an NIC 1524. The switch 1523 can selectively connect the processor 1521 and the storage device 1525 or the NIC 1524 and the storage device 1525 under the control of the processor 1521. Similarly, the application server 1510 may further include a switch 1513 and the NIC 1514.

In some example embodiments, the NIC 1524 may include a network interface card, network adapter, etc. The NIC 1524 may be connected to the network 1530 by a wired interface, wireless interface, Bluetooth interface, optical interface, etc. The NIC 1524 may include internal memory, DSP, a host bus interface, etc., and may be connected to the processor 1521 and/or the switch 1523 through the host bus interface. In some example embodiments, the NIC 1524 may be integrated with at least one of the processor 1521, the switch 1523, and the storage device 1525.

In the storage server 1520a, . . . , 1520m or the application server 1510a, . . . , 1510n, the processor may send commands to the storage devices 1515a, . . . , 1515n, 1525a, . . . , 1525m or the memories 1512a, . . . , 1512n, 1522a, . . . , 1522m to program or lead data. At this time, the data may be error-corrected data through an error correction code (ECC) engine. The data is data that has been processed through data bus inversion (DBI) or data masking (DM), and may include cyclic redundancy code (CRC) information. The data may be encrypted for security or privacy.

In some example embodiments, the application servers 1510a, . . . , 1510n may be implemented based on semiconductor devices including memory dies described with reference to FIGS. 1 to 14. A first memory die among a plurality of memory dies of a semiconductor device may generate an output clock signal by applying a clock option selected from a plurality of clock options to a reference clock signal. Here, each of the plurality of clock options may include a particular (or, alternatively, predetermined) degree of phase shift and/or delay. The first memory die may transmit a test pattern generated based on a particular (or, alternatively, predetermined) seed through the TSV as a test signal along with an output clock signal to the second memory die among the plurality of memory dies. The second memory die may capture a test signal based on the output clock signal. The second memory die may generate a comparison pattern based on the same seed as the first memory die and compare it with the captured test signal to generate a comparison result. At this time, the second memory die may capture the test signal in synchronization with the rising edge or falling edge of the output clock signal. The second memory die may determine the optimal clock option and the optimal edge type (rising edge or falling edge) among the plurality of clock options based on the comparison result. Accordingly, the semiconductor device can determine optimal data transmission conditions even if a random delay occurs through the TSV during data transmission.

The storage devices 1525a, . . . , 1525m may transmit control signals and command/address signals to the NAND flash memory devices 1527a, . . . , 1527m in response to the read command received from the processor.

A controller 1526 may generally control the operation of the storage device 1525. In some example embodiments, the controller 1526 may include static random access memory (SRAM). The controller 1526 may write data to the NAND flash 1527 in response to a write command, or may read data from the NAND flash 1527 in response to a read command. For example, the write commands and/or read commands may come from a processor 1521 within the storage server 1520, a processor 1521m within another storage server 1520m, or a processor 1511a, 1511n within an application server 1510a, . . . , 1510n.

As described herein, any devices, systems, modules, portions, units, controllers, circuits, and/or portions thereof according to any of the example embodiments, and/or any portions thereof (including, without limitation, the semiconductor device 10, the test circuits 103_1 to 103_4, the semiconductor device 20, the first die 21, the CPU 211, the test circuit 213, the pattern generator 2131, the first FIFO (First-In First-Out) circuit 2133, the pattern comparator 2135, the second FIFO circuit 2137, the near via logic NVL 215, the plurality of TSVs 217_1 and 217_3, the second die 23, the CPU 231, the test circuit 233, the pattern generator 2331, the first FIFO circuit 2333, the pattern comparator 2335, the second FIFO circuit 2337, the NVL 235, the plurality of TSVs 237_1 and 237_3, the reference die 30, the CPU 301, the clock generator 303, the clock divider 305, the special function register SFR 307, the pattern generator 309, the result storage buffer 311, the pattern comparator 315, the transmitter 313, the FIFO circuit 3131, the NVL circuit 3133, the clock regulator 3135, the receiver 317, the first NVL circuit 3133a, the second NVL circuit 3133b, the third NVL circuit 3133c, the plurality of phase shifters 3136a, 3136b, 3136c, and 3136d, the delay unit 3138, the first selector 3137, the second selector 3139, the target die 60, the CPU 601, the clock generator 603, the clock divider 605, the SFR 607, the pattern generator 609, the result storage buffer 611, the transmitter 613, the pattern comparator 615, the pattern generator 6151, the comparator 6153, the receiver 617, the FIFO circuit 6171, the plurality of NVL circuits 6173, the edge selector 6175, the first NVL circuit 6173a, the second NVL circuit 6173b, the third NVL circuit 6173c, the first flip-flop 6176a, the second flip-flop 6176b, the first selector 6177, the second selector 6179, semiconductor device 1200, the first die 120, the clock generator 1203, the clock divider 1205, the transmitter 1207, the clock regulator 1213, the FIFO circuit 1209, the NVL circuit 1211, the second die 130, the receiver 1217, the FIFO circuit 1219, the plurality of NVL circuits 1221, the edge selector 1223, the memory die 1300, the area 1301 for transmitting a clock signal, the area 1303 where the FIFO circuit of the transmitter is located, the TSV area 1305 of the transmitter, the area 1307 for receiving a clock signal, the area 1309 where the FIFO circuit is located, the TSV area 1311 of the receiver, the core area 1313, the semiconductor device 1400, the package substrate 1410, the interposer 1420, the stacked semiconductor chip 1430, the system-on-chip SOC 1450, the memory chip 1440, the buffer chip 1460, the data center 1500, application servers 1510a, . . . , 1510n and storage servers 1520a, . . . , 1520m, processor 1511a, . . . , 1511n, memories 1512a, . . . , 1512n, switches 1513a, . . . , 1513n, storage devices 1515a, . . . , 1515n, NICs 1414a, . . . , 1414n, memories 1522a, . . . , 1522m, processor 1521a, . . . , 1521m, switches 1523a, . . . , 1523m, NICs 1524a, . . . , 1524m, storage devices 1525a, . . . , 1525m, CTRLs 1526a, . . . , 1526m, NVMs 1527a, . . . , 1527m, network 1530, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Although some example embodiments of the present inventive concepts have been described in detail above, the scope of the present inventive concepts is not limited thereto, and various modifications and improvements can be made by those skilled in the art using the basic concepts of the present inventive concepts defined in the following claims.

What is claimed is:

1. A semiconductor device, comprising:
a reference die configured to
generate a test signal based on a first seed, and
transmit both an output clock signal and the test signal; and
a target die configured to
receive the output clock signal as an input clock signal through at least one through-silicon via TSV,
capture the test signal as captured data based on the input clock signal, and
compare a comparison pattern generated based on the first seed and the captured data.

2. The semiconductor device of claim 1, wherein:
the reference die comprises
a clock generator configured to generate a reference clock signal, and
a clock regulator configured to generate the output clock signal based on applying both a particular phase shift and a particular delay to the reference clock signal.

3. The semiconductor device of claim 2, wherein:
the clock regulator comprises
a first phase shifter configured to perform a first phase shift on the reference clock signal,
a second phase shifter configured to perform a second phase shift on the reference clock signal,
a third phase shifter configured to perform a third phase shift on the reference clock signal,
a fourth phase shifter configured to perform a fourth phase shift on the reference clock signal, and
a first selector connected to each of the first phase shifter, the second phase shifter, the third phase shifter, and the fourth phase shifter, the first selector configured to select one shifted reference clock signal of a plurality of shifted reference clock signals generated by one phase shifter of the first to fourth phase shifters as a phase shift signal.

4. The semiconductor device of claim 3, wherein:
the clock regulator comprises
a delay unit connected to the first selector, the delay unit configured to receive the phase shift signal from the first selector, the delay unit configured to generate a phase delay signal based on applying a first delay to the phase shift signal, and
a second selector configured to select one of the phase shift signal or the phase delay signal as the output clock signal.

5. The semiconductor device of claim 2, wherein:
the reference die further includes a pattern generator configured to generate a test pattern based on the first seed according to a linear feedback shift register (LFSR) algorithm.

6. The semiconductor device of claim 5, wherein:
the reference die further comprises
a first-in first-out (FIFO) circuit configured to receive the test pattern and to transmit the test pattern as the test signal based on the reference clock signal, and
a near via logic (NVL) circuit configured to transmit the test signal to the TSV to cause the TSV to transmit the test signal to the target die.

7. The semiconductor device of claim 2, wherein:
the reference die further comprises
a first special function register SFR, the first special function register SFR configured to
store a plurality of clock options for generating the output clock signal based on the first seed and the reference clock signal, and
transmit a clock selection signal indicating one clock option of the plurality of clock options to the clock regulator.

8. The semiconductor device of claim 1, wherein:
the target die comprises
a first flip-flop configured to capture the test signal as a first data signal in synchronization with a falling edge of the input clock signal,
a second flip-flop configured to capture the test signal as a second data signal in synchronization with a rising edge of the input clock signal, and
an edge selector connected to the first flip-flop and the second flip-flop, the edge selector configured to output one data signal of the first data signal or the second data signal as the captured data.

9. The semiconductor device of claim 8, wherein:
the target die further comprises
a pattern comparator configured to compare the captured data and the comparison pattern to generate a comparison result, and
a second SFR configured to transmit, to the edge selector, an edge selection signal for selecting an edge type for capturing the first seed and the test signal.

10. The semiconductor device of claim 9, wherein:
the target die further includes a result storage buffer configured to store clock information and the comparison result, the comparison result corresponding to the clock information, the clock information including the edge type and a clock option of the reference die.

11. The semiconductor device of claim 1, wherein:
the reference die and the target die are stacked on each other.

12. A memory die, comprising:
a transmitter configured to
generate a first test signal based on a first seed, and
transmit both an output clock signal and the first test signal; and
a receiver configured to
receive a second test signal generated based on a second seed and an input clock signal through at least one through-silicon via TSV, and
capture the second test signal as captured data based on the input clock signal.

13. The memory die of claim 12, further comprising:
a clock generator configured to generate a reference clock signal, and
the transmitter includes a clock regulator configured to generate the output clock signal based on applying both a particular phase shift and a particular delay to the reference clock signal.

14. The memory die of claim 13, further comprising:
a special function register configured to
store a plurality of clock options for generating the output clock signal based on the first seed and the reference clock signal, and
transmit a clock selection signal indicating one clock option of the plurality of clock options to the clock regulator.

15. The memory die of claim 12, wherein:
the receiver comprises
a first flip-flop configured to capture the second test signal as a first data signal in synchronization with a falling edge of the input clock signal,
a second flip-flop configured to capture the second test signal as a second data signal in synchronization with a rising edge of the input clock signal, and
an edge selector connected to the first flip-flop and the second flip-flop, the edge selector configured to output one data signal of the first data signal and the second data signal as the captured data.

16. The memory die of claim 12, further comprising:
a pattern comparator configured to
generate a comparison pattern based on the second seed, and
compare the captured data and the comparison pattern.

17. A test method for a semiconductor device, the test method comprising:
generating a first test pattern based on a first seed;
storing the first test pattern in a first-in first-out FIFO circuit based on a reference clock signal;
generating an output clock signal based on modulating the reference clock signal;
receiving a ready signal indicating whether a target die is ready to receive a first test signal,
in response to a determination that the ready signal is at an enable level, transmitting a VALID signal to control an operation of the target die to the target die; and
transmitting the first test signal based on the output clock signal.

18. The test method of claim 17, wherein:
the generating the output clock signal comprises
generating the output clock signal based on applying a phase shift and delay to the reference clock signal based on a plurality of particular clock options.

19. The test method of claim 18, further comprising:
receiving, by the target die, the output clock signal as an input clock signal via at least one through-silicon via TSV,
in response to a determination that the VALID signal is at an enable level, capturing the first test signal as captured data based on the input clock signal to generate data,
generating first comparison data based on the first seed,
comparing the captured data and the first comparison data to generate a comparison result, and
selecting an optimal clock option among the plurality of particular clock options based on the comparison result.

20. The test method of claim 19, wherein:
capturing the first test signal comprises
capturing the test signal as one of a first data signal in synchronization with a falling edge of the input clock signal or a second data signal in synchronization with a rising edge of the input clock signal, based on an edge type associated with capturing the test signal.
